(19) United States
(12) Patent Application Publication
(10) Pub. No.: US 2025/0169385 A1
(43) Pub. Date: May 22, 2025

(54) SEMICONDUCTOR STRUCTURE AND OPERATING METHOD THEREOF

(71) Applicant: MACRONIX INTERNATIONAL CO., LTD., HSINCHU (TW)

(72) Inventors: Feng-Min LEE, Hsinchu City (TW); Yu-Yu LIN, New Taipei City (TW); Po-Hao TSENG, Taichung City (TW); Ming-Hsiu LEE, Hsinchu City (TW)

(21) Appl. No.: 18/631,117

(22) Filed: Apr. 10, 2024

Related U.S. Application Data
(60) Provisional application No. 63/601,236, filed on Nov. 21, 2023.

(51) Int. Cl. H10N 70/20; H10N 70/00

(52) U.S. Cl. CPC H10N 70/253; H10N 70/8825; H10N 70/8828

(57) ABSTRACT

A semiconductor structure includes a gate, a channel structure, a gate insulating layer, a source, and a drain. The channel structure includes a threshold switching material, in which the channel structure includes a layered channel, a columnar channel, or a plurality of nanosheet channels. The gate insulating layer is disposed between the gate and the channel structure. The source is in direct contact with the channel structure. The drain is in direct contact with the channel structure.

### CROSS-REFERENCE TO RELATED APPLICATION

This application claims priority to U.S. Provisional Application Ser. No. 63/601,236, filed Nov. 21, 2023, which is herein incorporated by reference.

### BACKGROUND

### Field of Invention

The present disclosure relates to a semiconductor structure and an operating method thereof.

### Description of Related Art

In the back end of line (BEOL) process of integrated circuits, when manufacturing transistors, doped silicon may be used as a channel material; however, it is usually necessary to activate the dopants by a high temperature of 600° C. to 1000° C. The high temperature may damage metal wiring in the integrated circuits and thus reduce the performance of integrated circuits. For example, an oxide semiconductor may be used as a channel material. The oxide semiconductor has a lower process temperature but suffers from the problem of low carrier mobility. For example, a two-dimensional material may be used as a channel material. The two-dimensional material has a lower process temperature but suffers from the problem of poor uniformity. In view of the above, it is necessary to provide a new semiconductor structure to overcome the above problems.

### SUMMARY

The present disclosure provides a semiconductor structure including a first gate, a channel structure, a first gate insulating layer, a source, and a drain. The channel structure includes a threshold switching material, in which the channel structure includes a layered channel, a columnar channel, or a plurality of nanosheet channels. The first gate insulating layer is disposed between the first gate and the channel structure. The source is in direct contact with the channel structure. The drain is in direct contact with the channel structure.

In some embodiments, the threshold switching material includes an ovonic threshold switching material, a mixed-ionic-electronic-conduction material, a phase change material, or combinations thereof.

In some embodiments, the threshold switching material is a chalcogenide.

In some embodiments, the ovonic threshold switching material includes AsSeGe, InAsSeGe, SiAsSeGe, CAsSeGe, CTe, BTe, GeCTe, NGeCTe, or combinations thereof.

In some embodiments, the mixed-ionic-electronic-conduction material includes CuSbGeTe, CuSbGeSTe, or a combination thereof.

In some embodiments, the source and the drain are in contact with an upper surface of the channel structure, and the first gate insulating layer is disposed between the source and the drain.

In some embodiments, the channel structure is disposed on the source and the drain, the first gate insulating layer is disposed on the channel structure, and the first gate is disposed on the first gate insulating layer.

In some embodiments, the semiconductor structure further includes a second gate and a second gate insulating layer, in which the second gate insulating layer is disposed on the second gate, and the source and the drain are disposed on the second gate insulating layer.

In some embodiments, the source and the drain are disposed on the channel structure, the first gate insulating layer is disposed on the source and the drain, and the first gate is disposed on the first gate insulating layer.

In some embodiments, the semiconductor structure further includes a second gate and a second gate insulating layer, in which the second gate insulating layer is disposed on the second gate, and the channel structure is disposed on the second gate insulating layer.

In some embodiments, the first gate insulating layer is disposed on the first gate, the source and the drain are disposed on the first gate insulating layer, and the channel structure is disposed on the source and the drain.

In some embodiments, the first gate insulating layer is disposed on the first gate, the channel structure is disposed on the first gate insulating layer, and the source and the drain are disposed on the channel structure.

In some embodiments, the semiconductor structure further includes: a second gate and a second gate insulating layer, in which the second gate insulating layer is disposed on the second gate, the channel structure is disposed on the second gate insulating layer. In the source and the drain, a first one is in direct contact with an upper surface of the channel structure, and a second one is in direct contact with a lower surface of the channel structure. The first gate insulating layer is disposed on the channel structure, and the first gate is disposed on the first gate insulating layer.

In some embodiments, the first gate covers a plurality of sidewalls and a top surface of the channel structure.

In some embodiments, the channel structure includes the nanosheet channels, and the first gate surrounds the nanosheet channels.

In some embodiments, the semiconductor structure further includes an insulating layer, in which the insulating layer is disposed between the source and the drain, and the channel structure is in direct contact with a plurality of sidewalls of the insulating layer, the source, and the drain.

The present disclosure provides an operating method of a semiconductor structure, and it includes the following operations: receiving the semiconductor structure of any one of the above-mentioned embodiments; and applying a first voltage to the drain, in which an absolute value of the first voltage is greater than an absolute value of a switching threshold voltage of the threshold switching material of the channel structure.

In some embodiments, the operating method further includes: applying a second voltage to the first gate to control the switching threshold voltage of the threshold switching material of the channel structure.

In some embodiments, the threshold switching material is an ovonic threshold switching material, and the first voltage is a positive voltage.

In some embodiments, the threshold switching material is a mixed-ionic-electronic-conduction material, and the first voltage is a positive voltage or a negative voltage.

### BRIEF DESCRIPTION OF THE DRAWINGS

The present disclosure can be more fully understood by reading the following detailed description of the embodiments, with reference made to the accompanying drawings as follows.

FIG. 1 is a schematic cross-sectional view of a semiconductor structure according to various embodiments of the present disclosure.

FIG. 2A, FIG. 3A, FIG. 4, and FIG. 5A are schematic diagrams of operating semiconductor structures according to various embodiments of the present disclosure.

FIG. 2B is a diagram of drain current-drain voltage of operating the semiconductor structure of FIG. 2A.

FIG. 3B is a schematic diagram of drain current-drain voltage of operating the semiconductor structure of FIG. 3A.

FIG. 5B is a schematic diagram of drain current-drain voltage of operating the semiconductor structure of FIG. 5A.

FIG. 6, FIG. 7, FIG. 8, and FIG. 10 are schematic cross-sectional views of semiconductor structures according to various embodiments of the present disclosure.

FIG. 9A is a schematic perspective view of a semiconductor structure according to various embodiments of the present disclosure.

FIG. 9B is a schematic cross-sectional view of the semiconductor structure of FIG. 9A along a section line a-a according to various embodiments of the present disclosure.

FIG. 11 is a schematic perspective view of a semiconductor structure according to various embodiments of the present disclosure.

FIG. 12A is a schematic cross-sectional view of the semiconductor structure of FIG. 11 along a section line A-A′ according to various embodiments of the present disclosure.

FIG. 12B is a schematic cross-sectional view of the semiconductor structure of FIG. 11 along a section line B-B′ according to various embodiments of the present disclosure.

FIG. 13A is a schematic cross-sectional view of the semiconductor structure of FIG. 11 along a section line A-A′ according to various embodiments of the present disclosure.

FIG. 13B is a schematic cross-sectional view of the semiconductor structure of FIG. 11 along a section line B-B′ according to various embodiments of the present disclosure.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

It will be understood that, although the terms, first, second, third etc. may be used herein to describe various elements, components, regions, layers, and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

The present disclosure provides a semiconductor structure including a gate, a channel structure, a gate insulating layer, a source, and a drain. The semiconductor structure is a three-terminal switching device. The channel structure includes a threshold switching material, in which the channel structure includes a layered channel, a columnar channel, or a plurality of nanosheet channels. The gate insulating layer is disposed between the gate and channel structure. The source is in direct contact with the channel structure. The drain is in direct contact with the channel structure. The semiconductor structure of the present disclosure can be used as a transistor in a back end of line (BEOL) of monolithic 3-dimensional integration, for example, but it is not limited thereto. The channel structure of the present disclosure includes a threshold switching material. The threshold switching material can be fabricated into a channel structure at a lower process temperature (for example, equal to or lower than 500° C.) and still have high carrier mobility, so that high current can flow through the semiconductor structure when operating the semiconductor structure. Moreover, other components (such as metal circuits) within the monolithic 3-dimensional integration may not be damaged by the process temperature. Various embodiments of the present disclosure will be described below with drawings.

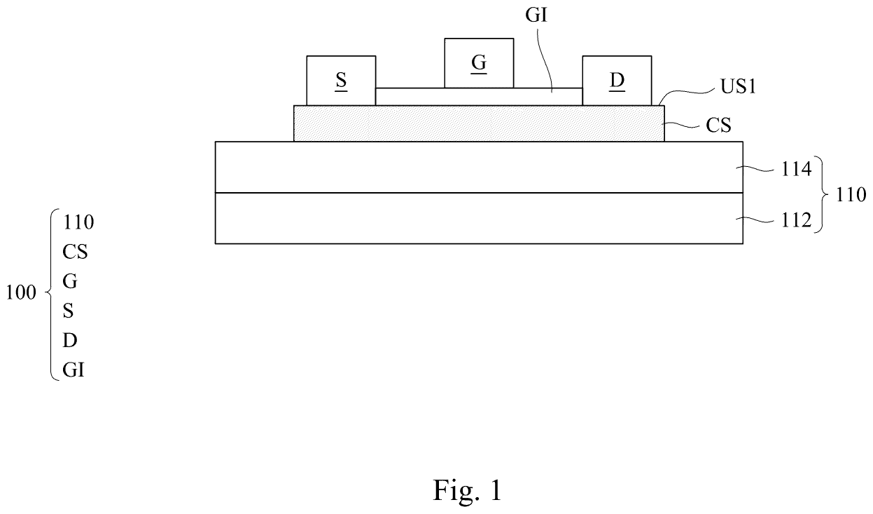

FIG. 1 is a schematic cross-sectional view of a semiconductor structure 100 according to various embodiments of the present disclosure. As shown in FIG. 1, the semiconductor structure 100 includes a substrate 110, a gate G, a channel structure CS, a gate insulating layer GI, a source S, and a drain D. The substrate 110 includes a substrate 112 and an insulating layer 114. In some embodiments, the substrate 112 is a semiconductor substrate or a glass substrate. In some embodiments, the substrate 112 includes any suitable semiconductor material. The semiconductor material includes, for example, one or more materials, such as crystalline silicon, silicon oxide, strained silicon, germanium silicon, doped or undoped polycrystalline silicon, germanium, gallium arsenide, other suitable semiconductor materials, or combinations thereof. In some embodiments, the insulating layer 114 includes an oxide, a nitride, or a combination thereof, such as silicon dioxide, silicon nitride, or a combination thereof. In some embodiments, the substrate 112 is a silicon wafer. The channel structure CS is disposed on the substrate 110. The channel structure CS includes a threshold switching material and is a layered channel. The gate G is disposed above the channel structure CS. The gate insulating layer GI is disposed between the gate G and the channel structure CS to separate the gate G and the channel structure CS, and the gate insulating layer GI is disposed between the source S and the drain D. The source S and the drain D are in direct contact with an upper surface US1 of the channel structure CS. In some embodiments, the gate insulating layer GI includes an oxide, a nitride, or a combination thereof, such as silicon dioxide, hafnium oxide, aluminum oxide, silicon nitride, or combinations thereof. In some embodiments, the gate G, the source S, and the drain D respectively include W, TiN, Pt, Ti, Ru, Mo, Al, Cu, or combinations thereof.

In some embodiments, the threshold switching material includes an ovonic threshold switching material, a mixed-ionic-electronic-conduction material, a phase change material, or combinations thereof. The phase change material is, for example, a Mott transition material. In some embodiments, the threshold switching material is a chalcogenide. In some embodiments, the ovonic threshold switching material is an arsenic-containing chalcogenide, an arsenic-free chalcogenide, or a combination thereof. In some embodiments, the ovonic threshold switching material includes AsSeGe, InAsSeGe, SiAsSeGe, CAsSeGe, CTe, BTe, GeCTe, NGeCTe, or combinations thereof. In some embodiments, the ovonic threshold switching material further includes one or more dopants, such as B, In, C, Si, S, or combinations thereof. In some material is a embodiments, the mixed-ionic-electronic-conduction copper-containing chalcogenide. In some embodiments, the mixed-ionic-electronic-conduction material includes CuSbGeTe, CuSbGeSTe, or a combination thereof. In some embodiments, the phase change material includes GeSbTe, SiGeSb, Sb₂Te₃, GeTe, Cr₂Ge₂Te₆, VO₂, MoO₂, V₂O₃, NbO₂, Fe₃O₄, FeS, Ta₂O₅, Ti₃O₅, Ti₂O₃, LaCoO₃, SmNiO₃, or combinations thereof, in which the element ratios in the GeSbTe and the SiGeSb can be adjusted arbitrarily. The performance of the phase change material is similar to that of the ovonic threshold switching material.

In some embodiments, the channel structure CS including the threshold switching material can be formed by sputtering, atomic layer deposition (ALD), or chemical vapor deposition (CVD). In some embodiments, the formation temperature is 100° C. to 500° C., such as 100, 150, 200, 250, 300, 350, 400, 450, or 500° C. It is worth noting that carriers have high mobility in the channel structure CS including the threshold switching material formed at a temperature equal to or lower than 400° C. Therefore, when the channel structure CS of the semiconductor structure 100 of the present disclosure is operated (turned on), a high current may flow through the semiconductor structure 100, and the current is, for example, greater than 5000000 A/cm².

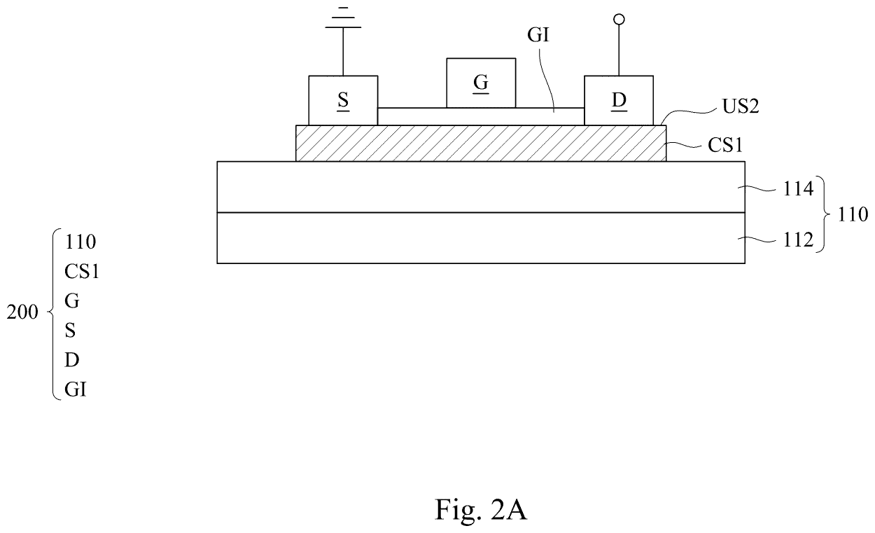

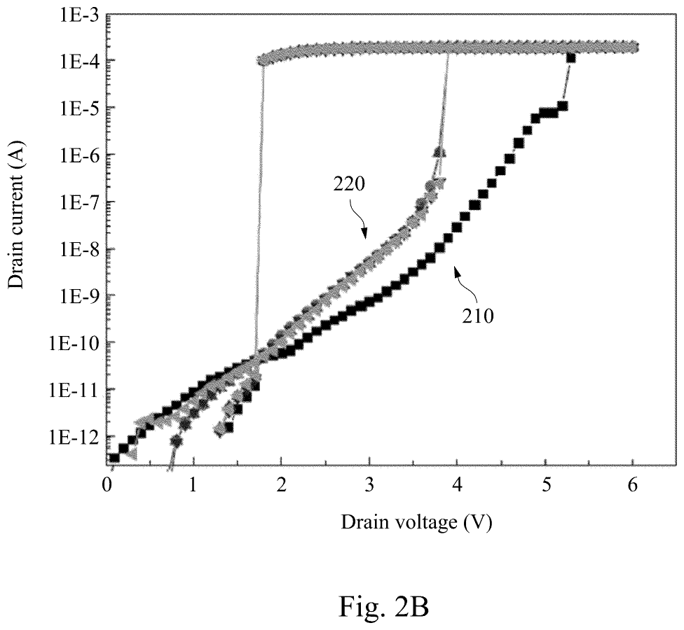

FIG. 2A is a schematic diagram of operating a semiconductor structure 200 according to various embodiments of the present disclosure. As shown in FIG. 2A, the semiconductor structure 200 includes a substrate 110, a gate G, a channel structure CS1, a gate insulating layer GI, a source S, and a drain D. The channel structure CS1 is an ovonic threshold switching material layer. In some embodiments, the ovonic threshold switching material layer is an arsenic-containing chalcogenide layer or an arsenic-free chalcogenide layer. In some embodiments, the ovonic threshold switching material layer includes AsSeGe, InAsSeGe, SiAsSeGe, CAsSeGe, CTe, BTe, GeCTe, NGeCTe, or combinations thereof. The channel structure CS1 is disposed on the substrate 110. The gate G is disposed above the channel structure CS1. The gate insulating layer GI is disposed between the gate G and the channel structure CS1 to separate the gate G and the channel structure CS1. Moreover, the gate insulating layer GI is disposed between the source S and the drain D. The source S and the drain D are in direct contact with an upper surface US2 of the channel structure CS1.

Please continue to refer to FIG. 2A. The semiconductor structure 200 is a three-terminal switching device. When operating the semiconductor structure 200, the source S can be grounded, a bias voltage can be applied to the drain D, and a bias voltage is not applied to the gate G. When no bias voltage is applied to the gate G, the semiconductor structure 200 can be used as a two-terminal switching device. More specifically, the present disclosure provides an operating method of the semiconductor structure 200, which includes the following operations: receiving the semiconductor structure 200. A first voltage is applied to the drain D. The absolute value of the first voltage is greater than the absolute value of the switching threshold voltage of the threshold switching material of the channel structure CS1, and the current can flow through the channel structure CS1.

FIG. 2B is a diagram of drain current-drain voltage of operating the semiconductor structure 200 of FIG. 2A, in which the channel structure CS1 is an In-doped AsSeGe layer. As shown in FIG. 2B, a line 210 is the result of the drain current changing with the drain voltage when the drain voltage is first applied. A plurality of lines 220 is the results of the drain current changing with the drain voltage when the drain voltage is applied for the second, third, fourth and fifth times. The lines 220 generally overlap. It can be seen from the line 210 and the lines 220 that when the drain voltage is higher than the switching threshold voltage of the channel structure CS1, current can flow through the channel structure CS1.

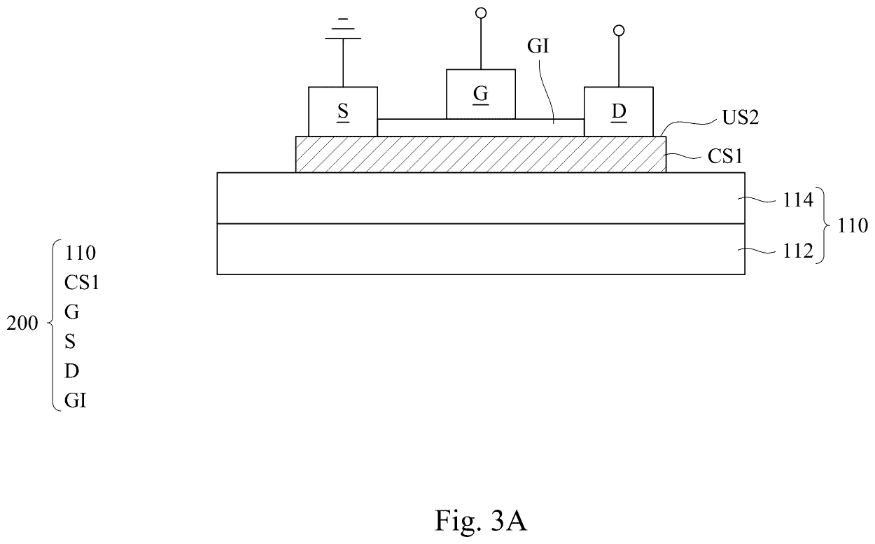

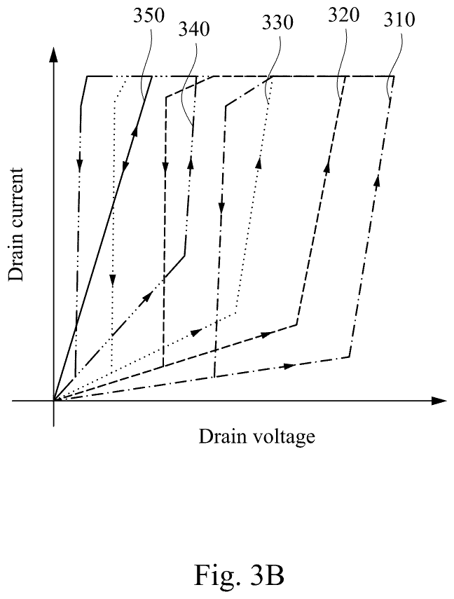

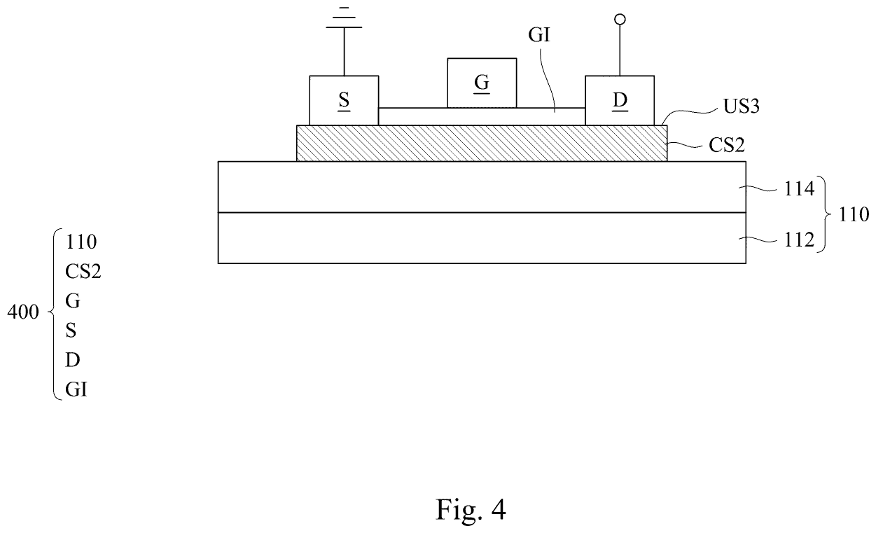

FIG. 3A is a schematic diagram of operating the semiconductor structure 200 according to various embodiments of the present disclosure. The semiconductor structure 200 is a three-terminal switching device. When operating the semiconductor structure 200, the source S can be grounded, a bias voltage can be applied to the drain D, and a bias voltage can be applied to the gate G. More specifically, the present disclosure provides an operating method of the semiconductor structure 200, and it includes the following operations: receiving the semiconductor structure 200. A first voltage is applied to the drain D, and the absolute value of the first voltage is greater than the absolute value of the switching threshold voltage of the threshold switching material of the channel structure CS1. A second voltage is applied to the gate G to control the switching threshold voltage of the threshold switching material of the channel structure CS1, in which the threshold switching material is the ovonic threshold switching material, and the first voltage is a positive voltage. The switching performance of the semiconductor structure 200, such as switching threshold voltage, holding voltage, and forming voltage, is adjustable and controllable. When a positive voltage is applied to gate G, an electric field will be formed in the vertical direction in the channel structure CS1, so that electrons in the channel structure CS1 accumulate on the upper part of the channel structure CS1. Therefore, the semiconductor structure 200 is easier to be turned on. The switching threshold voltage and the holding voltage of the channel structure CS1 may decrease as the second voltage increases. When a negative voltage is applied to the gate G, an electric field will be formed in the vertical direction in the channel structure CS1, thereby making the electrons in the channel structure CS1 move away from the upper part of the channel structure CS1. Therefore, the semiconductor structure 200 is less likely to be turned on. By the above operating method, the semiconductor structure 200 can be turned on, and current may flow through the channel structure CS1.

FIG. 3B is a schematic diagram of drain current-drain voltage of operating the semiconductor structure 200 of FIG. 3A, in which the channel structure CS1 is an In-doped AsSeGe layer. The line 310 is the result of the variation of the drain current with the drain voltage when −2 V is applied to the gate G. The line 320 is the result of the variation of the drain current with the drain voltage when 0 V is applied to the gate G. The line 330 is the result of the variation of the drain current with the drain voltage when 2 V is applied to the gate G. The line 340 is the result of the variation of the drain current with the drain voltage when 4 V is applied to the gate G. The line 350 is the result of the variation of the drain current with the drain voltage when 6 V is applied to the gate G. It can be seen from the above lines that the electrical performance of the semiconductor structure 200 can be controlled by the voltage applied to the gate G. When a positive voltage is applied to the gate G, the electrons in the channel structure CS1 may be close to the upper surface US2, thereby making the semiconductor structure 200 easier to be turned on. Therefore, the switching threshold voltage and the holding voltage of the channel structure CS1 may decrease as the voltage applied to the gate G increases. When −2 V is applied to the gate G, the leakage current becomes smaller. When 6 V is applied to the gate G, the drain current-drain voltage has a linear relationship, which is consistent with Ohm's law.

FIG. 4 is a schematic diagram of operating a semiconductor structure 400 according to various embodiments of the present disclosure. As shown in FIG. 4, the semiconductor structure 400 includes a substrate 110, a gate G, a channel structure CS2, a gate insulating layer GI, a source S, and a drain D. The channel structure CS2 is a mixed-ionic-electronic-conduction material layer. In some embodiments, the mixed-ionic-electronic-conduction material layer is a copper-containing chalcogenide layer. In some embodiments, the mixed-ionic-electronic-conduction material layer includes CuSbGeTe, CuSbGeSTe, or a combination thereof. The channel structure CS2 is disposed on the substrate 110. The gate G is disposed above the channel structure CS2. The gate insulating layer GI is disposed between the gate G and the channel structure CS2 to separate the gate G and the channel structure CS2. Moreover, the gate insulating layer GI is disposed between the source S and the drain D. The source S and the drain D are in direct contact with an upper surface US3 of the channel structure CS2.

Please continue to refer to FIG. 4. The semiconductor structure 400 is a three-terminal switching device. When operating the semiconductor structure 400, the source S can be grounded, a bias voltage can be applied to the drain D, and a bias voltage is not applied to the gate G. When no bias voltage is applied to the gate G, the semiconductor structure 400 can be used as a two-terminal switching device. More specifically, the present disclosure provides an operating method of the semiconductor structure 400, and it includes the following operations: receiving the semiconductor structure 400. A first voltage is applied to the drain D. The absolute value of the first voltage is greater than the absolute value of the switching threshold voltage of the threshold switching material of the channel structure CS2, and the current may flow through the channel structure CS2. The channel structure CS2 is a mixed-ionic-electronic-conduction material layer, and the mixed-ionic-electronic-conduction material is bipolar. The first voltage can be a positive voltage or a negative voltage. When the absolute value of the positive voltage or the negative voltage applied to the drain D is greater than the absolute value of the switching threshold voltage of the mixed-ionic-electronic-conduction material, the semiconductor structure 400 can be turned on.

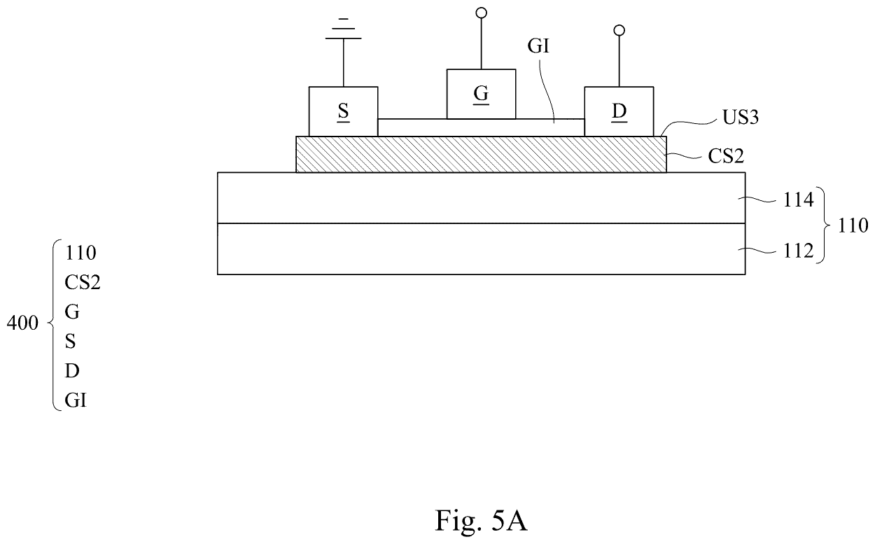

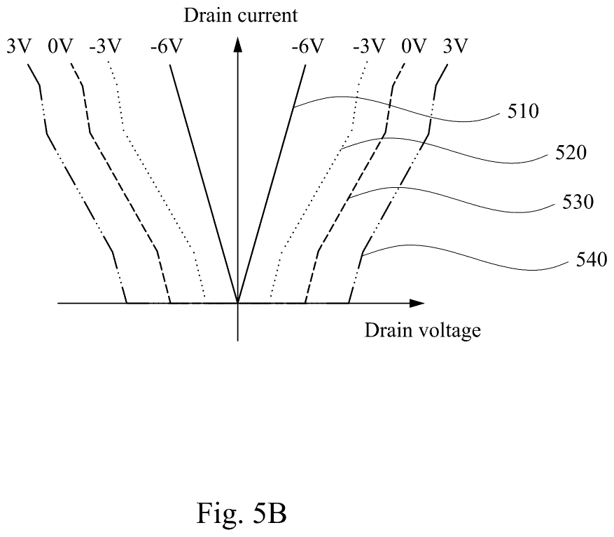

FIG. 5A is a schematic diagram of operating the semiconductor structure 400 according to various embodiments of the present disclosure. The semiconductor structure 400 is a three-terminal switching device. When operating the semiconductor structure 400, the source S can be grounded, a bias voltage can be applied to the drain D, and a bias voltage can be applied to the gate G. More specifically, the present disclosure provides an operating method of the semiconductor structure 400, and it includes the following operations: receiving the semiconductor structure 400. A first voltage is applied to the drain D, and the absolute value of the first voltage is greater than the absolute value of the switching threshold voltage of the threshold switching material of the channel structure CS2, in which the first voltage is a positive voltage or a negative voltage. A second voltage is applied to the gate G to control the switching threshold voltage of the threshold switching material of the channel structure CS2, in which the threshold switching material is a mixed-ionic-electronic-conduction material. The switching behavior of the semiconductor structure 400 is adjustable and controllable. When a negative voltage is applied to the gate G, an electric field will be formed in the vertical direction in the channel structure CS2, so that the cations (such as copper ions) in the channel structure CS2 accumulate on the upper part of the channel structure CS2. Therefore, the semiconductor structure 400 is easier to be turned on. The switching threshold voltage and the holding voltage of the channel structure CS2 may become smaller as the second voltage decreases. When a positive voltage is applied to the gate G, an electric field will be formed in the vertical direction in the channel structure CS2, thereby making the cations (such as copper ions) in the channel structure CS2 move away from the upper part of the channel structure CS2. Therefore, the semiconductor structure 400 is less likely to be turned on. By the above operating method, the semiconductor structure 400 can be turned on, and current may flow through the channel structure CS2.

FIG. 5B is a schematic diagram of drain current-drain voltage of operating the semiconductor structure 400 of FIG. 5A, in which the channel structure CS2 is CuSbGeSTe layer. The line 510 is the result of the variation of the drain current with the drain voltage when −6 V is applied to the gate G. The line 520 is the result of the variation of the drain current with the drain voltage when −3 V is applied to the gate G. The line 530 is the result of the variation of the drain current with the drain voltage when 0 V is applied to the gate G. The line 540 is the result of the variation of the drain current with the drain voltage when 3 V is applied to the gate G. It can be seen from the above lines that the electrical performance of the semiconductor structure 400 can be controlled by the voltage applied to the gate G. When a negative voltage is applied to the gate G, the copper ions in the channel structure CS2 may be close to the upper surface US3, thereby making the semiconductor structure 400 easier to be turned on. Therefore, the switching threshold voltage and the holding voltage of the channel structure CS2 may become smaller as the voltage applied to the gate G decreases. When 3 V is applied to the gate G, the leakage current becomes smaller. When −6 V is applied to the gate G, the drain current-drain voltage has a linear relationship, which is consistent with Ohm's law.

Regarding the materials, the operating methods, and the advantages of the semiconductor structures of various embodiments described later in the present disclosure, please refer to the aforementioned embodiments of the semiconductor structures in FIG. 1 to FIG. 5B.

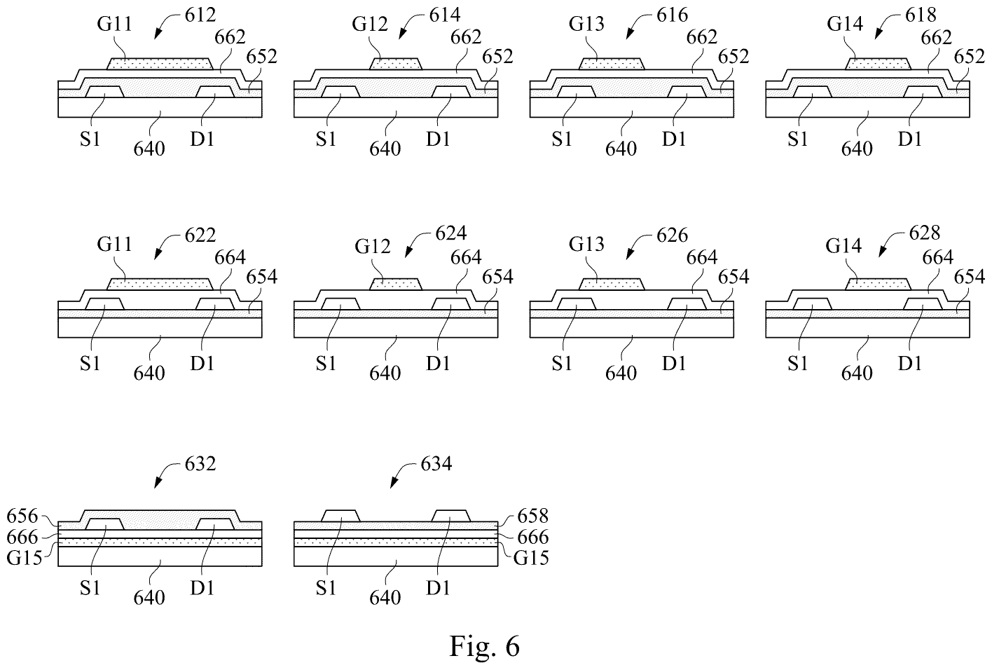

FIG. 6, FIG. 7, and FIG. 8 are schematic cross-sectional views of semiconductor structures according to various embodiments of the present disclosure. The channel structures in FIG. 6, FIG. 7 and FIG. 8 are layered channels.

As shown in FIG. 6, a semiconductor structure 612 includes a substrate 640, a source S1, a drain D1, a channel structure 652, a first gate insulating layer 662, and a first gate G11. The source S1 and the drain D1 are disposed on the substrate 640. The channel structure 652 is disposed on the source S1 and the drain D1. The first gate insulating layer 662 is disposed on the channel structure 652. The first gate G11 is disposed on the first gate insulating layer 662. In the semiconductor structure 612, the projection of the first gate G11 on the substrate 640 overlaps with the projection of the source S1 and the drain D1 on the substrate 640. As shown in FIG. 6, the difference between the semiconductor structure 612 and a semiconductor structure 614 is that the lengths of the first gate G11 and the first gate G12 are different. In the semiconductor structure 614, the projection of the first gate G12 on the substrate 640 does not overlap with the projections of the source S1 and drain D1 on the substrate 640. As shown in FIG. 6, the difference between the semiconductor structure 612 and a semiconductor structure 616 is that the lengths of the first gate G11 and the first gate G13 are different. In the semiconductor structure 616, the projection of the first gate G13 on the substrate 640 overlaps with the projection of the source S1 on the substrate 640, but does not overlap with the projection of the drain D1 on the substrate 640. As shown in FIG. 6, the difference between the semiconductor structure 612 and a semiconductor structure 618 is that the lengths of the first gate G11 and the first gate G14 are different. In the semiconductor structure 618, the projection of the first gate G14 on the substrate 640 overlaps with the projection of the drain D1 on the substrate 640, but does not overlap with the projection of the source S1 on the substrate 640.

As shown in FIG. 6, a semiconductor structure 622 includes a substrate 640, a source S1, a drain D1, a channel structure 654, a first gate insulating layer 664, and a first gate G11. The channel structure 654 is disposed on the substrate 640. The source S1 and the drain D1 are disposed on the channel structure 654. The first gate insulating layer 664 is disposed on the source S1 and the drain D1. The first gate G11 is disposed on the first gate insulating layer 664. In the semiconductor structure 622, the projection of the first gate G11 on the substrate 640 overlaps with the projection of the source S1 and the drain D1 on the substrate 640. As shown in FIG. 6, the difference between the semiconductor structure 622 and a semiconductor structure 624 is that the lengths of the first gate G11 and the first gate G12 are different. In the semiconductor structure 624, the projection of the first gate G12 on the substrate 640 does not overlap with the projections of the source S1 and the drain D1 on the substrate 640. As shown in FIG. 6, the difference between the semiconductor structure 622 and a semiconductor structure 626 is that the lengths of the first gate G11 and the first gate G13 are different. In the semiconductor structure 626, the projection of the first gate G13 on the substrate 640 overlaps with the projection of the source S1 on the substrate 640, but does not overlap with the projection of the drain D1 on the substrate 640. As shown in FIG. 6, the difference between the semiconductor structure 622 and a semiconductor structure 628 is that the lengths of the first gate G11 and the first gate G14 are different. In the semiconductor structure 628, the projection of the first gate G14 on the substrate 640 overlaps with the projection of the drain D1 on the substrate 640, but does not overlap with the projection of the source S1 on the substrate 640.

As shown in FIG. 6, a semiconductor structure 632 includes a substrate 640, a source S1, a drain D1, a channel structure 656, a gate insulating layer 666, and a gate G15. The gate G15 is disposed on the substrate 640. The gate insulating layer 666 is disposed on the gate G15. The source S1 and the drain D1 are disposed on the gate insulating layer 666. The channel structure 656 is disposed on the source S1 and the drain D1. As shown in FIG. 6, a semiconductor structure 634 includes a substrate 640, a source S1, a drain D1, a channel structure 658, a gate insulating layer 666, and a gate G15. The gate G15 is disposed on the substrate 640. The gate insulating layer 666 is disposed on the gate G15. The channel structure 656 is disposed on the gate insulating layer 666. The source S1 and the drain D1 are disposed on the channel structure 656.

As shown in FIG. 7, a semiconductor structure 712 includes a substrate 640, a source S1, a drain D1, a channel structure 652, a first gate insulating layer 662, a second gate insulating layer 668, a first gate G11, and a second gate G21. The difference between the semiconductor structure 712 and the semiconductor structure 612 is that the semiconductor structure 712 further includes: the second gate G21 and the second gate insulating layer 668, in which the second gate G21 is disposed on the substrate 640, and the second gate insulating layer 668 is disposed on the second gate G21, the source S1 and the drain D1 are disposed on the second gate insulating layer 668. The thicknesses of the first gate insulating layer 662 and the second gate insulating layer 668 are the same or different. The first gate insulating layer 662 may be thicker than the second gate insulating layer 668, or the second gate insulating layer 668 may be thicker than the first gate insulating layer 662. Similarly, compared with the semiconductor structures 614, 616, and 618, the semiconductor structures 714, 716, and 718 respectively include: the second gate G21 and the second gate insulating layer 668, in which the second gate G21 is disposed on the substrate 640, the second gate insulating layer 668 is disposed on the second gate G21, and the source S1 and the drain D1 are disposed on the second gate insulating layer 668.

As shown in FIG. 7, a semiconductor structure 722 includes a substrate 640, a source S1, a drain D1, a channel structure 654, a first gate insulating layer 664, a second gate insulating layer 668, a first gate G11, and a second gate G21. The difference between semiconductor structure 722 and semiconductor structure 622 is that semiconductor structure 722 further includes: the second gate G21 and the second gate insulating layer 668, in which the second gate G21 is disposed on the substrate 640, the second gate insulating layer 668 is disposed on the second gate G21, the channel structure 654 is disposed on the second gate insulating layer 668. The thicknesses of the first gate insulating layer 664 and the second gate insulating layer 668 are the same or different. The first gate insulating layer 664 may be thicker than the second gate insulating layer 668, or the second gate insulating layer 668 may be thicker than the first gate insulating layer 664. Similarly, compared with the semiconductor structures 624, 626, and 628, the semiconductor structures 724, 726, and 728 respectively include: the second gate G21 and the second gate insulating layer 668, in which the second gate G21 is disposed on the substrate 640, and the second gate insulating layer 668 It is disposed on the second gate G21, and the channel structure 654 is disposed on the second gate insulating layer 668.

Please continue to refer to FIG. 7. The operating method for controlling the switching threshold voltages of the channel structures 652 and 654 includes: applying a first voltage to the first gate G11, and applying a second voltage to the second gate G21. The first voltage and the second voltage can be the same or different. Since the channel structures 652 and 654 can be controlled by two gates, the channel structures 652 and 654 can be controlled more accurately, and the leakage currents of the channel structures 652 and 654 may be smaller.

As shown in FIG. 8, a semiconductor structure 812 includes a substrate 640, a first source/drain SD1, a second source/drain SD2, a channel structure 659, a first gate insulating layer 672, a second gate insulating layer 674, a first gate G11, and a second gate G21. The second gate G21 is disposed on the substrate 640. The second gate insulating layer 674 is disposed on the second gate G21. The channel structure 659 is disposed on the second gate insulating layer 674. The first source/drain SD1 is in contact with the upper surface of the channel structure 659, and the second source/drain SD2 is in contact with the lower surface of the channel structure 659. In some embodiments, in the first source/drain SD1 and the second source/drain SD2, one is a source, and the other is a drain. Therefore, among the source and the drain, the first one is in direct contact with the upper surface of the channel structure 659, and the second one is in direct contact with the lower surface of the channel structure 659. The first gate insulating layer 672 is disposed on the channel structure 659. The first gate G11 is disposed on the first gate insulating layer 672. The thicknesses of the first gate insulating layer 672 and the second gate insulating layer 674 may be the same or different. The first gate insulating layer 672 may be thicker than the second gate insulating layer 674, or the second gate insulating layer 674 may be thicker than the first gate insulating layer 672.

Please continue to refer to FIG. 8. In the semiconductor structure 812, the projection of the first gate G11 on the substrate 640 overlaps with the projection of the first source/drain SD1 and the second source/drain SD2 on the substrate 640. As shown in FIG. 8, the difference between the semiconductor structure 812 and a semiconductor structure 814 is that the lengths of the first gate G11 and the first gate G12 are different. In the semiconductor structure 814, the projection of the first gate G12 on the substrate 640 does not overlap with the projections of the first source/drain SD1 and the second source/drain SD2 on the substrate 640. As shown in FIG. 8, the difference between the semiconductor structure 812 and the semiconductor structure 816 is that the lengths of the first gate G11 and the first gate G13 are different. In the semiconductor structure 816, the projection of the first gate G13 on the substrate 640 overlaps with the projection of the first source/drain SD1 on the substrate 640, but does not overlap with the projection of the second source/drain SD2 on the substrate 640. As shown in FIG. 6, the difference between the semiconductor structure 612 and the semiconductor structure 618 is that the lengths of the first gate G11 and the first gate G14 are different. In the semiconductor structure 618, the projection of the first gate G14 on the substrate 640 overlaps with the projection of the second source/drain SD2 on the substrate 640, but does not overlap with the projection of the first source/drain SD1 on the substrate 640.

Please continue to refer to FIG. 8. The operating method for controlling the switching threshold voltage of the channel structure 659 includes: applying a first voltage to the first gate G11, and applying a second voltage to the second gate G21. The first voltage and the second voltage may be the same or different. Since the channel structure 659 can be controlled by two gates, the channel structure 659 can be controlled more accurately, and the leakage current of the channel structure 659 may be smaller.

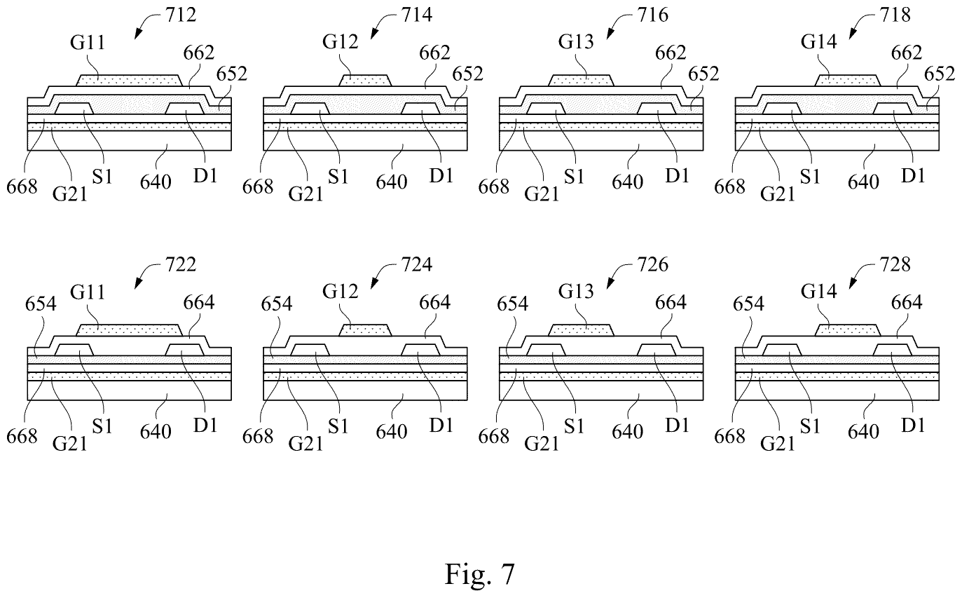

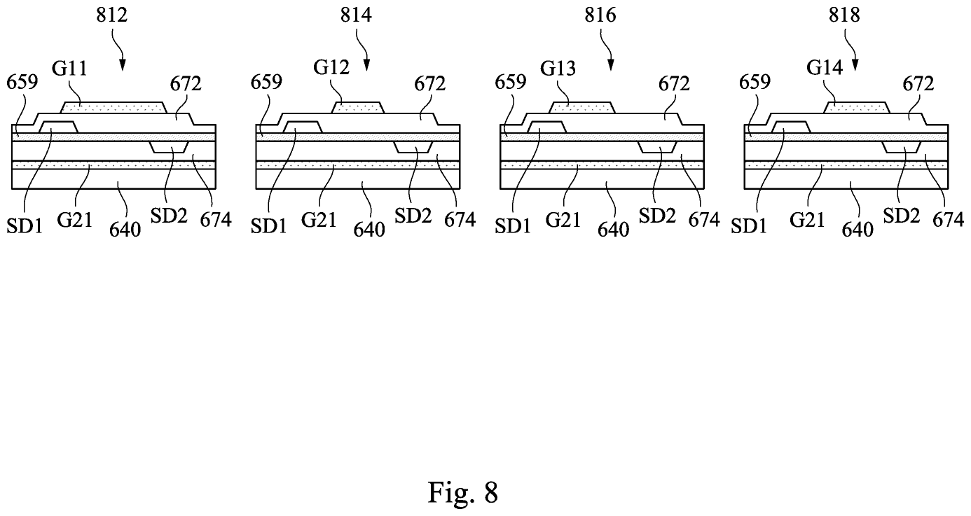

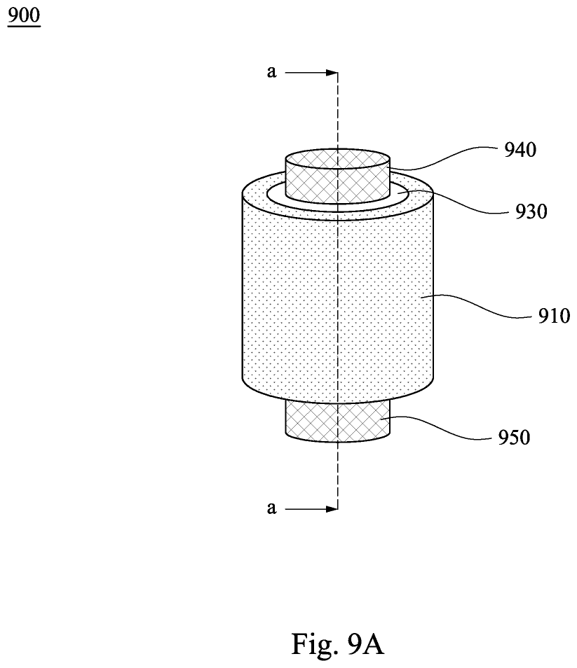

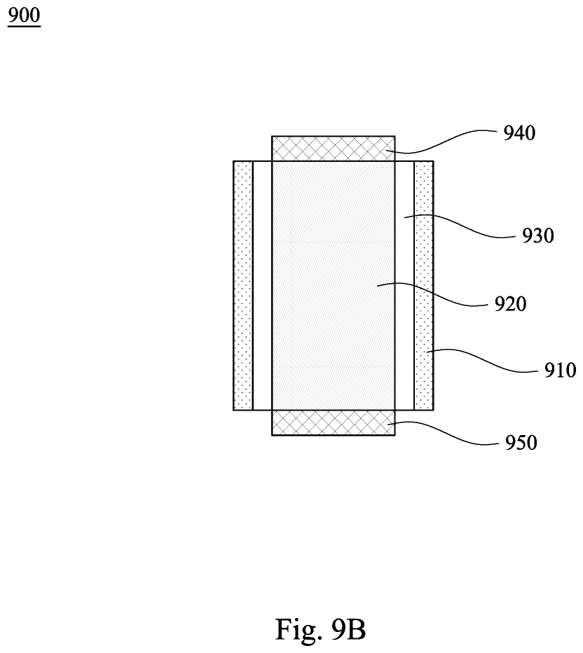

FIG. 9A is a schematic perspective view of a semiconductor structure 900 according to various embodiments of the present disclosure. FIG. 9B is a schematic cross-sectional view of the semiconductor structure 900 of FIG. 9A along section line a-a according to various embodiments of the present disclosure. As shown in FIG. 9A, the semiconductor structure 900 includes a gate 910, a channel structure 920, a gate insulating layer 930, a drain 940, and a source 950. The gate insulating layer 930 surrounds the channel structure 920, in which the channel structure 920 is a columnar channel. The gate 910 surrounds the gate insulating layer 930 and is separated from the channel structure 920 by the gate insulating layer 930. The drain 940 and the source 950 are respectively in contact with the ends of the channel structure 920.

FIG. 10 is a schematic cross-sectional view of a semiconductor structure 1000 according to various embodiments of the present disclosure. The semiconductor structure 1000 includes a substrate 1010, a stack 1020, a channel structure 1030, a gate insulating layer 1040, and a gate 1050. The channel structure 1030 is a layered channel. The stack 1020 includes a plurality of source/drain layers 1022 and a plurality of insulating layers 1024 that are alternately stacked. The channel structure 1030 covers the sidewall of the stack 1020. In more detail, the channel structure 1030 is in direct contact with a plurality of sidewalls of the source/drain layers 1022 and the insulating layers 1024. Each source/drain layer 1022 may be a source or a drain. For example, two adjacent source/drain layers 1022 are source and drain respectively, the insulating layer 1024 is disposed between the source/drain layers 1022, and the channel structure 1030 is in direct contact with a plurality of sidewalls of the source and drain. The gate insulating layer 1040 covers the channel structure 1030. The gate 1050 covers the gate insulating layer 1040. When the semiconductor structure 1000 is operated, the current flowing through the channel structure 1030 is substantially perpendicular to the upper surface of the substrate 1010. When a voltage is applied to the gate 1050, an induced electric field can be generated in the gate insulating layer 1040, and the induced electric field can control whether the channel structure 1030 is on or off. When the conduction state of the channel structure 1030 is to be read, a voltage can be applied between any two source/drain layers 1022 to read the current value. In addition, the numbers of the source/drain layers 1022 and the insulating layers 1024 in the stack 1020 can be adjusted arbitrarily according to design requirements. In some embodiments, the insulating layer 1024 includes an oxide, a nitride, or a combination thereof, such as silicon dioxide, silicon nitride, or a combination thereof.

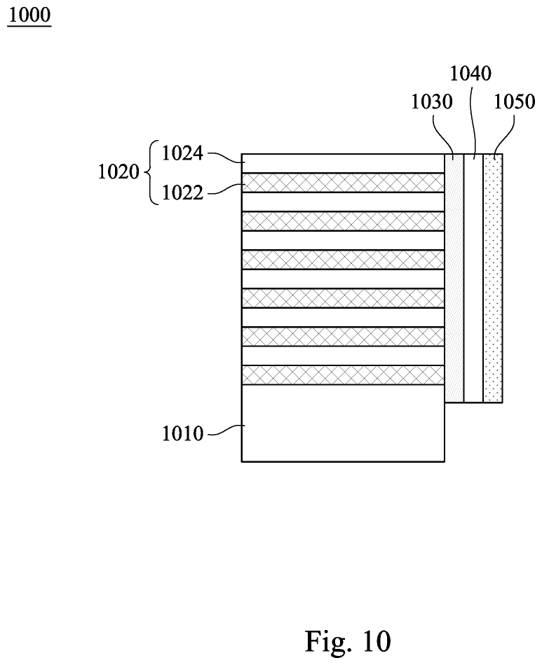

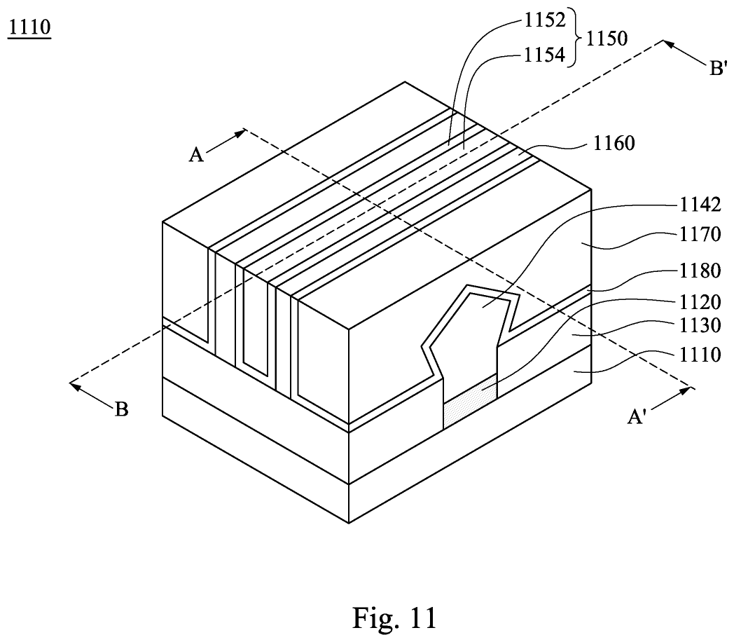

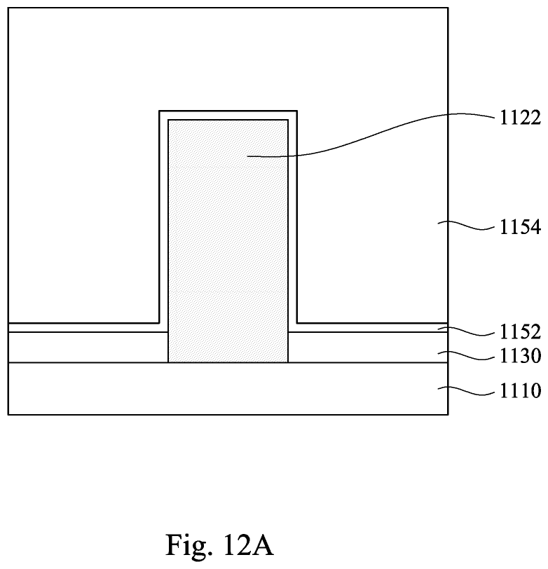

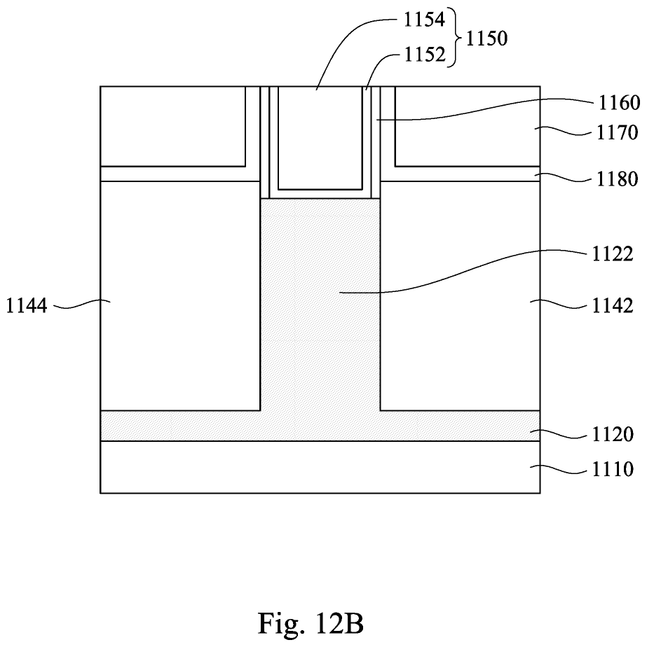

FIG. 11 is a schematic perspective view of a semiconductor structure 1110 according to various embodiments of the present disclosure. When the semiconductor structure 1110 is a fin field-effect transistor (FinFET), please refer to FIG. 12A for the schematic cross-sectional view of the semiconductor structure 1110 along a section line A-A′, and please refer to FIG. 12B for the schematic cross-sectional view of the semiconductor structure 1110 along a section line B-B′. As shown in FIG. 11, FIG. 12A, and FIG. 12B, the semiconductor structure 1110 includes a substrate 1010, a threshold switching material layer 1120, isolation structures 1130, a source 1142, a drain 1144, a gate structure 1150, gate spacers 1160, a contact etching stop layer (CESL layer) 1180, and an interlayer dielectric layer (ILD layer) 1170. The threshold switching material layer 1120 is disposed on the substrate 1010. The threshold switching material layer 1120 has at least one channel structure 1122. The channel structure 1122 is a fin structure and is also a layered channel. Although FIG. 12A only shows one fin structure, the number of the fin structure can be adjusted arbitrarily according to design requirements. The isolation structures 1130 may be shallow trench isolation (STI) structures. The isolation structures 1130 are used to separate adjacent channel structures 1122. The channel structure 1122 may protrude above and between adjacent isolation structures 1130. The gate structure 1150 is across the channel structure 1122 and covers a plurality of sidewalls and a top surface of the channel structure 1122. In more detail, the gate structure 1150 includes a gate insulating layer 1152 and a gate 1154. The gate insulating layer 1152 is disposed between the channel structure 1122 and the gate 1154. The gate 1154 covers the gate insulating layer 1152 and a plurality of sidewalls and a top surface of the channel structure 1122. The gate insulating layer 1152 may include an interfacial layer (IL layer) and a high k gate insulating layer located on the interfacial layer. For example, the interfacial layer includes silicon oxide or the like. For example, the high k gate insulating layer includes a metal oxide, such as hafnium oxide, hafnium silicon oxide, hafnium silicon oxynitride, tantalum hafnium oxide, hafnium titanium oxide, lanthanum oxide, zirconium oxide, titanium oxide, tantalum oxide, yttrium oxide, barium zirconium oxide, aluminum oxide, or combinations thereof. A pair of gate spacers 1160 is across the channel structure 1122 and is disposed on both sides of the gate structure 1150. The source 1142 and the drain 1144 are respectively disposed on both sides of the channel structure 1122 and directly contact the channel structure 1122. The contact etch stop layer 1180 covers the gate spacers 1160, the upper surface of the source 1142, and the upper surface of the drain 1144. The interlayer dielectric layer 1170 covers the contact etch stop layer 1180.

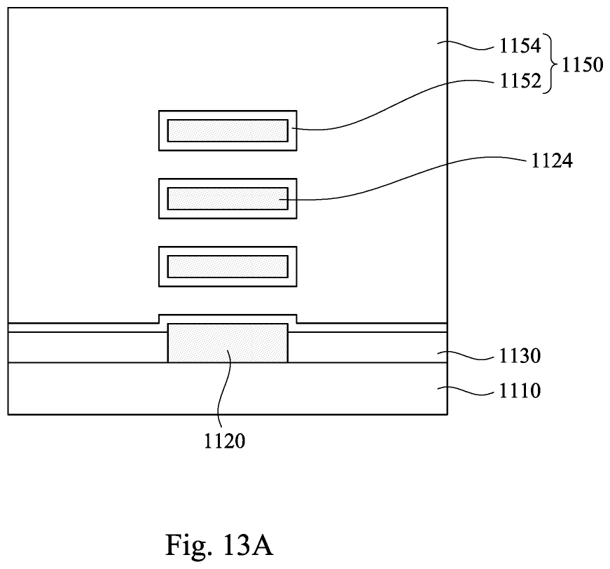

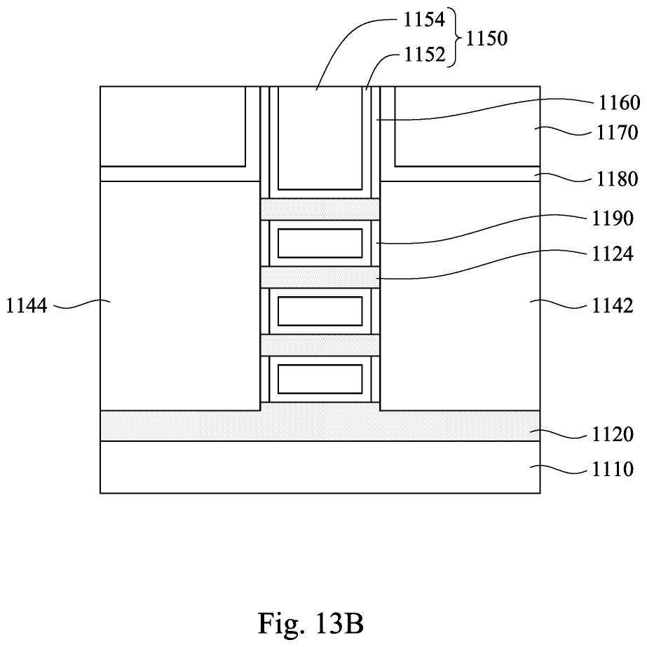

Please refer to FIG. 11 again. When the semiconductor structure 1110 is a gate-all-around transistor (GAA), please refer to FIG. 13A for the schematic cross-sectional view of the semiconductor structure 1110 along the section line A-A′, and please refer to FIG. 13B for the schematic cross-sectional view of the semiconductor structure 1110 along the section line B-B′. As shown in FIG. 11, FIG. 13A, and FIG. 13B, the semiconductor structure 1110 includes the substrate 1010, the threshold switching material layer 1120, the isolation structures 1130, the source 1142, the drain 1144, the gate structure 1150, the gate spacers 1160, the contact etching stop layer 1180, the interlayer dielectric layer 1170, and a plurality of inner spacers 1190. The threshold switching material layer 1120 is disposed on the substrate 1010. The threshold switching material layer 1120 has at least one channel structure 1124, and the channel structure 1124 includes a plurality of nanosheet channels. Although FIG. 13A only shows three nanosheet channels, the number of the nanosheet channels can be adjusted arbitrarily according to design requirements. The isolation structures 1130 may be STI structures. The gate structure 1150 surrounds the nanosheet channels. In more detail, the gate structure 1150 includes the gate insulating layer 1152 and the gate 1154. The gate insulating layer 1152 is disposed between the channel structure 1124 and the gate 1154. The gate 1154 surrounds the nanosheet channels. The gate insulating layer 1152 may include an interfacial layer and a high k gate insulating layer located on the interfacial layer. The inner spacers 1190 are sandwiched between the gate structure 1150 and the source 1142 and between the gate structure 1150 and the drain 1144. A pair of gate spacers 1160 is across the channel structure 1122 and is disposed on both sides of the gate structure 1150. The source 1142 and the drain 1144 are respectively disposed on both sides of the channel structure 1124 including the nanosheet channels, and are in direct contact with the channel structure 1124. The contact etch stop layer 1180 covers the gate spacers 1160, the upper surface of the source 1142, and the upper surface of the drain 1144. The interlayer dielectric layer 1170 covers the contact etch stop layer 1180.

In summary, the present disclosure provides a semiconductor structure and its operating method. The channel structure of the semiconductor structure includes a threshold switching material. The channel structure can be manufactured at a lower process temperature and still has high carrier mobility. Moreover, when the semiconductor structure of the present disclosure is integrated into a process such as BEOL, the process temperature used to form the channel structure does not damage other components, so that the other components maintain good electrical performance.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A semiconductor structure, comprising:
a first gate;
a channel structure comprising a threshold switching material, wherein the channel structure includes a layered channel, a columnar channel, or a plurality of nanosheet channels;
a first gate insulating layer disposed between the first gate and the channel structure;
a source being in direct contact with the channel structure; and
a drain being in direct contact with the channel structure.

2. The semiconductor structure of claim 1, wherein the threshold switching material includes an ovonic threshold switching material, a mixed-ionic-electronic-conduction material, a phase change material, or combinations thereof.

3. The semiconductor structure of claim 2, wherein the threshold switching material is a chalcogenide.

4. The semiconductor structure of claim 2, wherein the ovonic threshold switching material comprises AsSeGe, InAsSeGe, SiAsSeGe, CAsSeGe, CTe, BTe, GeCTe, NGeCTe, or combinations thereof.

5. The semiconductor structure of claim 2, wherein the mixed-ionic-electronic-conduction material comprises CuSbGeTe, CuSbGeSTe, or a combination thereof.

6. The semiconductor structure of claim 1, wherein the source and the drain are in contact with an upper surface of the channel structure, and the first gate insulating layer is disposed between the source and the drain.

7. The semiconductor structure of claim 1, wherein the channel structure is disposed on the source and the drain, the first gate insulating layer is disposed on the channel structure, and the first gate is disposed on the first gate insulating layer.

8. The semiconductor structure of claim 7, further comprising: a second gate and a second gate insulating layer, wherein the second gate insulating layer is disposed on the second gate, and the source and the drain are disposed on the second gate insulating layer.

9. The semiconductor structure of claim 1, wherein the source and the drain are disposed on the channel structure, the first gate insulating layer is disposed on the source and the drain, and the first gate is disposed on the first gate insulating layer.

10. The semiconductor structure of claim 9, further comprising: a second gate and a second gate insulating layer, wherein the second gate insulating layer is disposed on the second gate, and the channel structure is disposed on the second gate insulating layer.

11. The semiconductor structure of claim 1, wherein the first gate insulating layer is disposed on the first gate, the source and the drain are disposed on the first gate insulating layer, and the channel structure is disposed on the source and the drain.

12. The semiconductor structure of claim 1, wherein the first gate insulating layer is disposed on the first gate, the channel structure is disposed on the first gate insulating layer, and the source and the drain are disposed on the channel structure.

13. The semiconductor structure of claim 1, further comprising: a second gate and a second gate insulating layer, wherein the second gate insulating layer is disposed on the second gate, the channel structure is disposed on the second gate insulating layer, in the source and the drain, a first one is in direct contact with an upper surface of the channel structure, a second one is in direct contact with a lower surface of the channel structure, the first gate insulating layer is disposed on the channel structure, and the first gate is disposed on the first gate insulating layer.

14. The semiconductor structure of claim 1, wherein the first gate covers a plurality of sidewalls and a top surface of the channel structure.

15. The semiconductor structure of claim 1, wherein the channel structure comprises the nanosheet channels, and the first gate surrounds the nanosheet channels.

16. The semiconductor structure of claim 1, further comprising an insulating layer, wherein the insulating layer is disposed between the source and the drain, and the channel structure is in direct contact with a plurality of sidewalls of the insulating layer, the source, and the drain.

17. An operating method of a semiconductor structure, comprising:
receiving the semiconductor structure of claim 1; and
applying a first voltage to the drain, wherein an absolute value of the first voltage is greater than an absolute value of a switching threshold voltage of the threshold switching material of the channel structure.

18. The operating method of claim 17, further comprising: applying a second voltage to the first gate to control the switching threshold voltage of the threshold switching material of the channel structure.

19. The operating method of claim 17, wherein the threshold switching material is an ovonic threshold switching material, and the first voltage is a positive voltage.

20. The operating method of claim 17, wherein the threshold switching material is a mixed-ionic-electronic-conduction material, and the first voltage is a positive voltage or a negative voltage.
